(19) United States
(12) Patent Application Publication
(10) Pub. No.: US 2011/0298480 A1
(43) Pub. Date: Dec. 8, 2011

(54) Compensation of parasitic capacitances of capacitive sensors

(75) Inventors: Frank Kronmueller, Neudenau (DE); Horst Knoedgen, Munich (DE)

(73) Assignee: Digital Imaging Systems GmbH

(21) Appl. No.: 12/802,413

(22) Filed: Jun. 7, 2010

(51) Int. Cl. G01R 27/26

(52) U.S. Cl. 324/684; 318/135

(57) ABSTRACT

Circuits and methods for compensating the impact of parasitic capacitances on capacitive sensors have been achieved. The charge of a compensation capacitor assigned to each capacitive sensor is used to neutralize the charge of the parasitic capacitor.

### RELATED APPLICATION

This application is related to the following US patent applications:

DI08-002, titled “Distance measurement with capacitive sensor”, Ser. No. 12/290,386, filing date Oct. 30, 2008, and
DI08-006, titled “Camera Shutter and position control thereof”, Ser. No. 12/658,280, filing date Feb. 5, 2010,
and the above applications are assigned to the same assignee and are herein incorporated by reference in its entirety.

### BACKGROUND OF THE INVENTION

(1) Field of the Invention

This invention relates generally to the field of capacitive sensors and relates more specifically to compensation of parasitic capacitances of capacitive sensors.

(2) Description of the Prior Art

Capacitive sensors are capacitors separated by a dielectric material; often the electrodes used have the form of plates. Using the properties and knowledge of electric field and capacitance between separated charged electrodes/plates it is possible to retrieve information about distance, pressure, etc. The distance between the plates or the active area of neighboring plates, i.e. the capacitance can be used to measure a distance of objects.

The capacitance C is a measure of the charge stored on each plate for a given voltage where

$$C = \frac{ɛ \times A}{d} ,$$

wherein ∈ is the permittivity of the dielectric, A is the area of the plates and d is the distance as the plates are separated. As the plates separate there is a direct relation between the capacitance and the distance d of the plates. In case the plates shift in parallel there is also a direct relation between the distance of the shift of the plates and the capacitance. This relationship can be used in sensing position and proximity by using the capacitance relationship to displacement.

Capacitive sensing is a technology for detecting proximity, position, etc., based on capacitive coupling effects. Capacitive sensors can determine variables to be measured that affect the coupling capacitance between two or more electrodes. Capacitive sensors typically include measurement circuitry coupled to the electrodes. The measurement circuitry detects changes in the capacitance between the two or more electrodes. AC impedance is measured of the generated electric field and is translated into a DC output voltage. This information is further processed at an external micro controller with an ADC.

A drawback to capacitive sensors, especially those operating with small values/changes of capacitances is parasitic capacitances, which can heavily influence accuracy of capacitive sensors. Parasitic capacitances can exist always everywhere such as e.g. on chip and in printed circuits. Parasitic capacitances can't really totally avoid, they can reduce signals from a capacitive sensor by a factor up to 10 or even higher. Therefore it is important to compensate the negative effects of parasitic capacitances upon capacitive sensors.

Solutions dealing with capacitive sensors having parasitic capacitances are described in following patents:

U.S. Patent Publication (US 2009/0322353 to Ungaretti et al.) teaches a capacitive sensor and a detection structure of a microelectromechanical type, provided with a fixed element and a mobile element, capacitively coupled to one another, generating a capacitive variation as a function of a quantity to be detected, and with a parasitic coupling element, capacitively coupled to at least one between the mobile element and the fixed element generating a first parasitic capacitance, intrinsic to the detection structure; a readout-interface circuit is connected to the detection structure and generates, on an output terminal thereof, an output signal as a function of the capacitive variation. The readout-interface circuit has a feedback path between the output terminal and the parasitic coupling element so as to drive the first intrinsic parasitic capacitance with the output signal.

U.S. Patent Publication (US 2009/0153152 to Maharyta et al.) discloses a capacitive sensor that may include a transmit electrode and a receive electrode capacitively coupled with the transmit electrode. A capacitance sensing circuit senses a capacitance between the transmit and receive electrodes by applying a signal to the transmit electrode and rectifying a current waveform induced at the receive electrode. A compensation circuit reduces the effect of a mutual and parasitic capacitances of the transmit and receive electrode pair by adding a compensation current to the rectified current.

U.S. Patent Publication (US 2009/0160461 to Zangl et al.) discloses a system including a capacitive sensor including a first electrode and a second electrode. The system includes a measurement system configured to sense a capacitance between the first electrode and the second electrode and apply a first offset to the sensed capacitance to provide an offset compensated capacitance.

### SUMMARY OF THE INVENTION

A principal object of the present invention is to achieve capacitive sensors having strong output signals.

A further object of the present invention is to compensate the impact of parasitic capacitances on capacitive sensors.

In accordance with the objects of this invention a method to compensate the impact of parasitic capacitances on capacitive sensors has been achieved. The method invented comprises, firstly, the steps of: (1) providing one or more capacitive sensors wherein each sensor having an digital-to-analog converter, parasitic capacitances in parallel, a compensation capacitor, and a parasitic capacitance is present between a signal line of the capacitive sensors and ground, (2) charging, driven by clock pulses, the one or more compensation capacitors with a same, but inverted charge as the related parasitic capacitances, and (3) neutralizing, driven by clock cycles, in a next step charges of the one or more parasitic capacitances by inverted charges of the correspondent compensation capacitors. Furthermore the method invented comprises the steps of: (4) neutralizing the parasitic capacitance between the signal line and ground by a switch which is also driven by the clock pulses, and (5) sensing the capacitance of solely the capacitive sensor at output of the circuit, wherein the parasitic capacitances have been compensated in the previous steps.

In accordance with the objects of this invention a circuit to compensate the impact of parasitic capacitances on capacitive sensors has been achieved. The circuit invented firstly comprises: one or more capacitive sensors, wherein each sensor with a odd number has its first terminal connected to a positive input signal, each sensor with an even number has its first terminal connected to a negative input signal, and all second terminals are connected to a common signal output, and wherein each sensor comprises a parasitic capacitance in parallel to the capacitive sensor, a compensation capacitor having a second terminal connected to the second terminal of its correspondent capacitive sensor and a first terminal connected to the output of a differential operational amplifier, said differential operational amplifier having its positive input connected to ground and its negative input connected to an output of a digital-to-analog converter, and said digital-to-analog converter having a first terminal connected to the signal input of its capacitive sensor and a second terminal to the output of the operational amplifier. Furthermore the circuit invented comprises a parasitic capacitance between the output of the capacitive sensor and ground, and a switch in parallel to the parasitic capacitance between the sensor output and ground.

In accordance with the objects of this invention a circuit to compensate the impact of parasitic capacitances on capacitive sensors has been achieved. The circuit invented firstly comprises: one or more capacitive sensors, wherein each sensor has its first terminal connected to an output of a correspondent digital-to-analog converter, wherein each digital-to-analog converter with an even number has its input connected to a negative input clock signal, and all second terminals are connected to a common signal output, and wherein each sensor comprises: a parasitic capacitance in parallel to the capacitive sensor, a compensation capacitor having a second terminal connected via a third switch to the second terminal of the capacitive sensor and a first terminal connected via a second switch to the output of the digital-to-analog converter, and said digital-to-analog converter having a second terminal connected to ground. Furthermore each capacitive sensor comprises said second switch, said third switch, a fourth switch connected between the second terminal of the compensation capacitor and ground, and a fifth switch connected between the first terminal of the compensation capacitor and ground. Moreover the circuit comprises a parasitic capacitance between the output of the capacitive sensor and ground, and a first switch in parallel to the parasitic capacitance between the sensor output and ground.

### BRIEF DESCRIPTION OF THE DRAWINGS

In the accompanying drawings forming a material part of this description, there is shown:

FIG. 1 illustrates a block diagram showing the principal building blocks of a first embodiment of a circuit invented compensating parasitic capacitances.

FIG. 2 illustrates a block diagram showing the principal building blocks of a second embodiment of a circuit invented compensating parasitic capacitances.

FIG. 3 illustrates a flowchart of a method invented to compensate the impact of parasitic capacitances on capacitive sensors.

FIG. 4 shows an example of a pulse stream in regard of the circuit of FIG. 1.

### DESCRIPTION OF THE PREFERRED EMBODIMENTS

The preferred embodiments disclose methods and systems to compensate parasitic capacitances of capacitive sensors. In some preferred embodiments the invention is applied to sense an actual position of a moving object as e.g. the positions of shutter blades of a camera. Furthermore the invention could be applied to many other applications such as e.g. approximation sensor, wherein a body would act as a reflection plate, isolated data transmission, dielectric detection to detect fluids, plastic metal, etc.

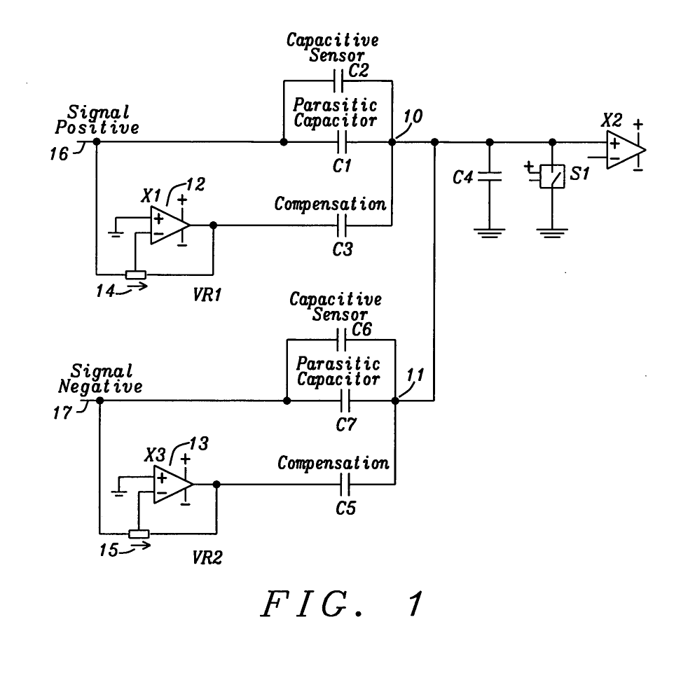

FIG. 1 illustrates a block diagram showing the principal building blocks of a first embodiment of a circuit invented compensating parasitic capacitances. A pair of capacitive sensors C2 and C6 is used to determine a position of an object, carrying one or more sensor plates that are to be moved to a target position. It should be noted that one or two or more than two capacitive sensors could be used with the present invention. Each sensor with a odd number (first, third, fifth, . . . sensor) has its first terminal connected to a positive input signal, each sensor with an even number (second, fourth, sixth . . . sensor) has its first terminal connected to a negative input signal, and all second terminals are connected to a common signal output.

Two sensor capacitors have been deployed in the preferred embodiment to enable a differential measurement of the position of the moving object. Each sensor capacitor has at least one plate on the moving object and one plate having a fixed position. Parasitic capacitances are assigned to each capacitive sensor, indicated by C1 and C7 and are assigned between output and ground, indicated by C4.

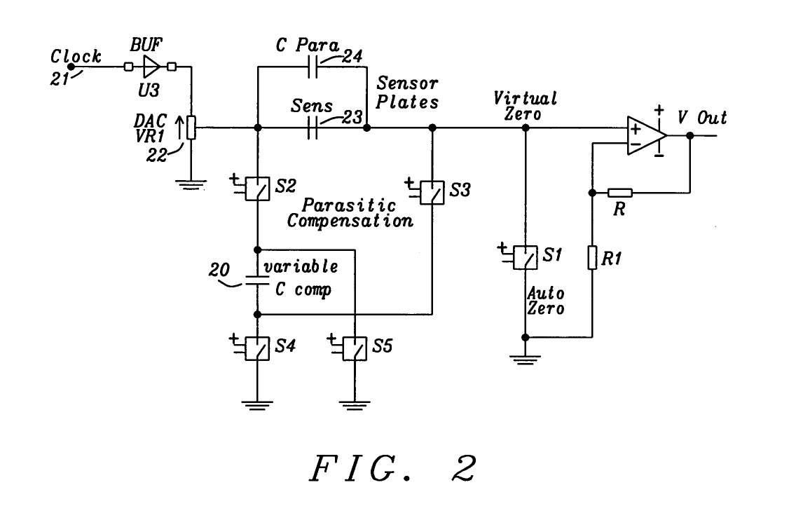

Key objective of the present invention is to compensate the charges on the parasitic capacitances C1, and C7 by deploying compensation capacitors C3 and C5 and to compensate parasitic capacitance C4 that is discharged by the controlled switch S1. It should be noted that in a preferred embodiment of the invention the compensation capacitors have a variable capacitance as outlined later in detail in regard of FIG. 2. The compensation charge should be higher than the charge of the parasitic capacitors.

The positive and negative clock pulses 16 and respectively 17 are converted from digital to analog values by digital-to-analog converters 14 and respectively 15.

Using the variable gain operational amplifiers 12 and 13, having both their negative input connected to the positive or respectively to the negative input signal, the compensation capacitors C3 and respectively C5 are both loaded with the same, but opposite charge of the correspondent parasitic capacitance C1 or respectively C7. Thus the effect of the parasitic capacitances C1 and C7 is neutralized in regard of nodes 10 or respectively 11, i.e. in regard of a following processing of the signals from the capacitive sensors C2 and C6. The switch S1 is only required for a reset of the system. Switch S1 is closed just before the system starts, hence causing an initial swing at the sensor, and after a short time switch S1 is opened and then the swings for the measurement start. The variable gain operational amplifiers 12 and 13 can modify the input pulses in order to stabilize the system.

The function of the operational amplifiers corresponds to the basic function. In some cases it will be better to have a stable capacitor and modifying the swing.

Switch S1 is required for the reset of the system. Before the system starts (swing at the sensor) switch S1 will be closed for a short time and than the swing for the measurements starts.

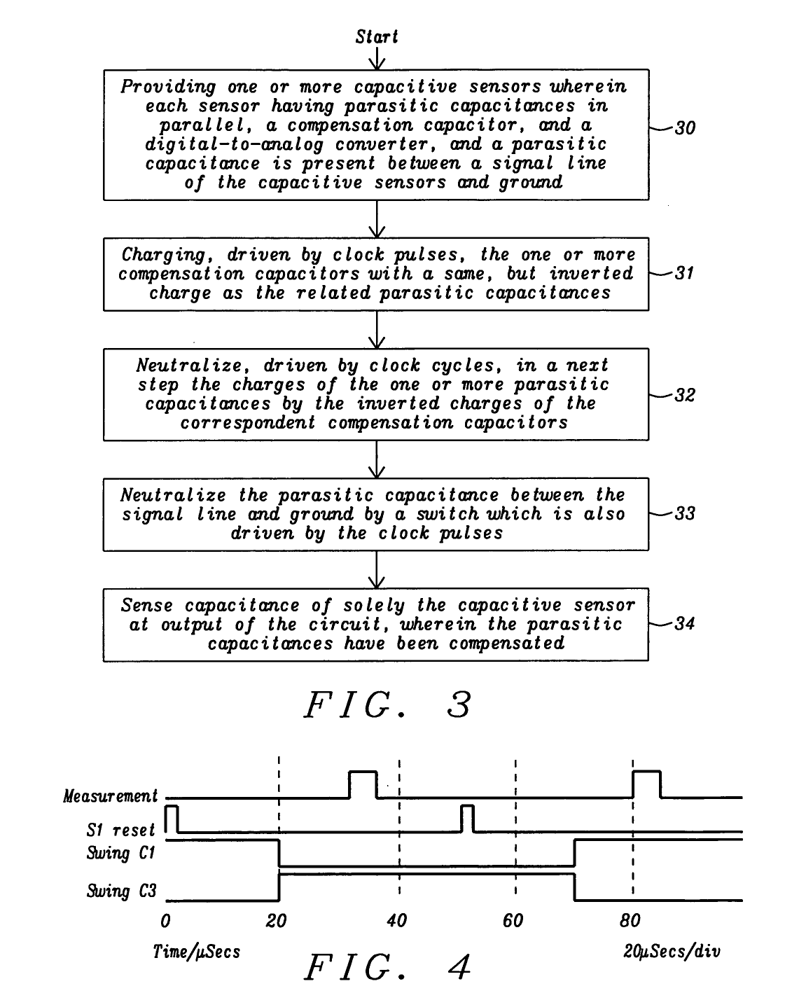

FIG. 4 shows an example of a pulse stream in regard of the circuit of FIG. 1. It demonstrates how the swing of the parasitic capacitance C1 is compensated by the swing of compensation capacitor C3 and the measurement pulse is kept.

FIG. 2 illustrates a block diagram showing the principal building blocks of a second embodiment of a circuit invented compensating parasitic capacitances. In this embodiment one sensor capacitor is used, it should be noted that two or more sensor capacitors could also be deployed with the type of embodiment of FIG. 2.

No operational amplifiers, as disclosed in FIG. 1 are used, but a variable compensation capacitor 20 is deployed. The variable capacitance has been achieved by using a capacitor array for adjustment. The operational capacitance of the compensation capacitor corresponds to the parasitic capacitance.

The capacitive array is adjusted by maximizing the output signal while moving the plate from one side to the other or have it set to one side at least. A maximum delta signal indicates that the parasitic capacitances are cancelled.

Furthermore FIG. 2 shows a capacitive sensor 23 and a parasitic capacitance is indicated by numeral 24. As in FIG. 1 another parasitic capacitance C4 is grounded by switch C1 periodically. The parasitic capacitance C4 is compensated by switches S1.

The switches S2 and S5 perform the inversion of the incoming clock signals 21. A digital-to-analog converter (DAC) 22 converts the incoming clock signals to analog signals. Furthermore an auto zero function in order to avoid any drift of the signal has been provided to the input of amplifier 25, e.g. as disclosed in the patent application DI08-006, titled “Distance measurement with capacitive sensor”, Ser. No. 12/658,280, filing date Feb. 5, 2010.

The compensation capacitor 20 is charged when switches S2 and S4 are closed and switches S3 and S5 are open. The charge of parasitic capacitance 24 is compensated by the charge of the compensation capacitor 20 while switches S3 and S5 are closed and switches S2 and S4 are open.

FIG. 3 illustrates a flowchart of a method invented to compensate the impact of parasitic capacitances on capacitive sensors. A first step 30 describes the provision of one or more capacitive sensors wherein each sensor having parasitic capacitances in parallel, a compensation capacitor, and a digital-to-analog converter, and a parasitic capacitance is present between a signal line of the capacitive sensors and ground. The following step 31 illustrates charging, driven by clock pulses, the one or more compensation capacitors with a same, but inverted charge as the related parasitic capacitances. The next step 32 depicts neutralizing; driven by clock cycles, in a next step the charges of the one or more parasitic capacitances by the inverted charges of the correspondent compensation capacitors. Step 33 illustrates neutralizing the parasitic capacitance between the signal line and ground by a switch that is also driven by the clock pulses, and, finally, step 34 depicts sensing the capacitance of solely the capacitive sensor at output of the circuit, wherein the parasitic capacitances have been compensated in the previous steps.

While the invention has been particularly shown and described with reference to the preferred embodiments thereof, it will be understood by those skilled in the art that various changes in form and details may be made without departing from the spirit and scope of the invention.

What is claimed is:

1. A method to compensate the impact of parasitic capacitances on capacitive sensors comprising the steps of:
(1) providing one or more capacitive sensors wherein each sensor having an digital-to-analog converter, parasitic capacitances in parallel, a compensation capacitor, and a parasitic capacitance is present between a signal line of the capacitive sensors and ground;
(2) charging, driven by clock pulses, the one or more compensation capacitors with a same, but inverted charge as the related parasitic capacitances;
(3) neutralizing, driven by clock cycles, in a next step charges of the one or to more parasitic capacitances by inverted charges of the correspondent compensation capacitors;
(4) neutralizing the parasitic capacitance between the signal line and ground by a switch which is also driven by the clock pulses; and
(5) sensing the capacitance of solely the capacitive sensor at output of the circuit, wherein the parasitic capacitances have been compensated in the previous steps.

2. The method of claim 1 wherein an operational amplifier, which is provided for each capacitive sensor, is inverting a pulse charging a correspondent compensation capacitor.

3. The method of claim 1 wherein said operational amplifier has a variable gain.

4. The method of claim 1 wherein an arrangement of switches, assigned to each compensation capacitor, is inverting a polarity of charge of the correspondent compensation capacitor required compensating the charge of the correspondent parasitic capacitance.

5. The method of claim 1 wherein said one or more compensation capacitors have a similar capacitance as the correspondent parasitic capacitances.

6. The method of claim 1 wherein the one or more compensation capacitors are each deployed a capacitor array.

7. The method of claim 1 wherein the compensation capacitors have a variable capacitance.

8. The method of claim 7 wherein the compensation capacitors are adjusted by generating a maximum output signal by moving one of the plates of the compensation capacitors and a maximum delta signal indicates that the parasitic capacitances are cancelled.

9. The method of claim 7 wherein the compensation capacitors are adjusted in a way that the charge on the compensation capacitors is higher than the charge on the correspondent parasitic capacitances.

10. The method of claim 1 wherein an auto-zero-function is provided to avoid any drift of the measurement signal.

11. A circuit to compensate the impact of parasitic capacitances on capacitive sensors comprising:
one or more capacitive sensors, wherein each sensor with a odd number has its first terminal connected to a positive input signal, each sensor with an even number has its first terminal connected to a negative input signal, and all second terminals are connected to a common signal output, and wherein each sensor comprises:
a parasitic capacitance in parallel to the capacitive sensor;
a compensation capacitor having a second terminal connected to the second terminal of its correspondent capacitive sensor and a first terminal to connected to the output of a differential operational amplifier;
said differential operational amplifier having its positive input connected to ground and its negative input connected to an output of a digital-to-analog converter; and
said digital-to-analog converter having a first terminal connected to the signal input of its capacitive sensor and a second terminal to the output of the operational amplifier;
a parasitic capacitance between the output of the capacitive sensor and ground; and
a switch in parallel to the parasitic capacitance between the sensor output and ground.

12. The circuit of claim 11 wherein said operational amplifier has a variable gain.

13. The circuit of claim 11 wherein the compensation capacitor has a variable capacitance.

14. The circuit of claim 13 wherein said compensation capacitor is an array of capacitors.

15. The circuit of claim 13 wherein the compensation capacitor is adjusted by generating a maximum output signal by moving one of the plates of the compensation capacitor and a maximum delta signal indicates that the correspondent parasitic capacitances are cancelled.

16. The circuit of claim 13 wherein the compensation capacitor is adjusted in a way that the charge on the compensation capacitors is higher than the charge on the correspondent parasitic capacitances.

17. The circuit of claim 11 wherein an auto-zero-function is provided to avoid any drift of the measurement signal.

18. A circuit to compensate the impact of parasitic capacitances on capacitive sensors comprising:
one or more capacitive sensors, wherein each sensor has its first terminal connected to an output of a correspondent digital-to-analog converter, wherein each digital-to-analog converter with an even number has its input connected to a negative input clock signal, and all second terminals are connected to a common signal output, and wherein each sensor comprises:
a parasitic capacitance in parallel to the capacitive sensor;
a compensation capacitor having a second terminal connected via a to third switch to the second terminal of the capacitive sensor and a first terminal connected via a second switch to the output of the digital-to-analog converter;
said digital-to-analog converter having a second terminal connected to ground;
said second switch;
said third switch;
a fourth switch connected between the second terminal of the compensation capacitor and ground; and
a fifth switch connected between the first terminal of the compensation capacitor and ground;
a parasitic capacitance between the output of the capacitive sensor and ground; and
a first switch in parallel to the parasitic capacitance between the sensor output and ground.

19. The circuit of claim 18 wherein the compensation capacitor has a variable capacitance.

20. The circuit of claim 19 wherein said compensation capacitor is an array of capacitors.

21. The circuit of claim 19 wherein the compensation capacitor is adjusted by generating a maximum output signal by moving one of the plates of the compensation capacitor and a maximum delta signal indicates that the correspondent parasitic capacitances are cancelled.

22. The circuit of claim 19 wherein the compensation capacitor is adjusted in a way that the charge on the compensation capacitors is higher than the charge on the correspondent parasitic capacitances.

23. The circuit of claim 18 wherein an auto-zero-function is provided to avoid any drift of the measurement signal.
